(19) United States
(12) Patent Application Publication
(10) Pub. No.: US 2008/0143317 A1
(43) Pub. Date: Jun. 19, 2008

(54) Resizable display

(75) Inventor: Vrajesh Dave, New York, NY (US)

Correspondence Address: LECROY CORPORATION, 700 CHESTNUT RIDGE ROAD, CHESTNUT RIDGE, NY, 10977, US

(73) Assignee: LeCroy Corporation, Chestnut Ridge, NY (US)

(21) Appl. No.: 11/641,154

(22) Filed: Dec. 19, 2006

(51) Int. Cl. G01R 23/14; H05K 5/02

(52) U.S. Cl. 324/76.41; 361/681

(57) ABSTRACT

A test and measurement apparatus is provided including a control panel; and a display. The display includes a first portion and a second portion. The second portion of the display is covered by the control panel. The control panel is adjustable to reveal at least a portion of the second portion of the display. The second portion of the display is inoperable when covered by the control panel and is operable when revealed.

### FIELD OF THE INVENTION

This invention is related generally to displays for displaying information, and more particularly to displays for displaying information where a control panel is available to aid in the control of the display of the information, and most particularly to an oscilloscope employing a front panel for controlling the oscilloscope and the display of information thereby.

### BACKGROUND OF THE INVENTION

When viewing information, it is well understood that having a larger display is generally better than having a small display. For example when using a test and measurement apparatus, information displayed on a smaller screen is more difficult to view. However, because of various additional, hardware constraints, such as control knobs, panels for controlling the apparatus, input and output ports, slots for receiving additional modules, increasing the size of the display has generally required a larger apparatus.

In an attempt to address this issue, manufacturers have contemplated doing away with some of the hardware requirements, such as a control panel, in favor of a digitally displayed “soft” control panel shown to a use on a portion of a display screen. While this control panel is preferable closeable, thus allowing the entire display to be used for information display, many users prefer a hardware based display control.

Therefore it would be beneficial to provide an improved apparatus that overcomes the drawbacks of the prior art.

Still other objects and advantages of the invention will in part be obvious and will in part be apparent from the specification and the drawings.

### SUMMARY OF THE INVENTION

Therefore, in accordance with the invention, a test and measurement apparatus is provided including an adjustable or removable control panel. Preferably, behind this adjustable or removable control panel resides an additional extended portion of a display. The control panel is selectively connectable to the front of the apparatus over the extended portion of the display so that when attached in place, the apparatus displays information only on the visible portion of the display. However, when the control panel is adjusted or removed to reveal the extended portion of the display, information is displayed on the original and extended portions of the display.

The control panel may be attached to the test and measurement apparatus in a wired or wireless manner in order to retain the functionality of the panel, even when physically detached from the apparatus. Of course, the control panel may also be disabled upon removal. In this case, displayed soft controls would allow for control of the apparatus by a user.

Therefore, in accordance with the invention a user is able to select whether to use the apparatus in a traditional configuration, or in an extended display mode, and furthermore when in the extended display mode, whether to employ the removed control panel or rely of displayed soft commands for control of the apparatus.

The invention accordingly comprises the features of construction, combination of elements, and arrangement of parts which will be exemplified in the construction hereinafter set forth, and the scope of the invention will be indicated in the claims.

### BRIEF DESCRIPTION OF THE DRAWINGS

For a more complete understanding of the invention, reference is made to the following description and accompanying drawings, in which:

FIG. 1 depicts a representation of an oscilloscope in accordance with the invention in which a removable control panel is in place in a traditional manner;

FIG. 2 depicts the oscilloscope of FIG. 1 with the removable control panel removed; and

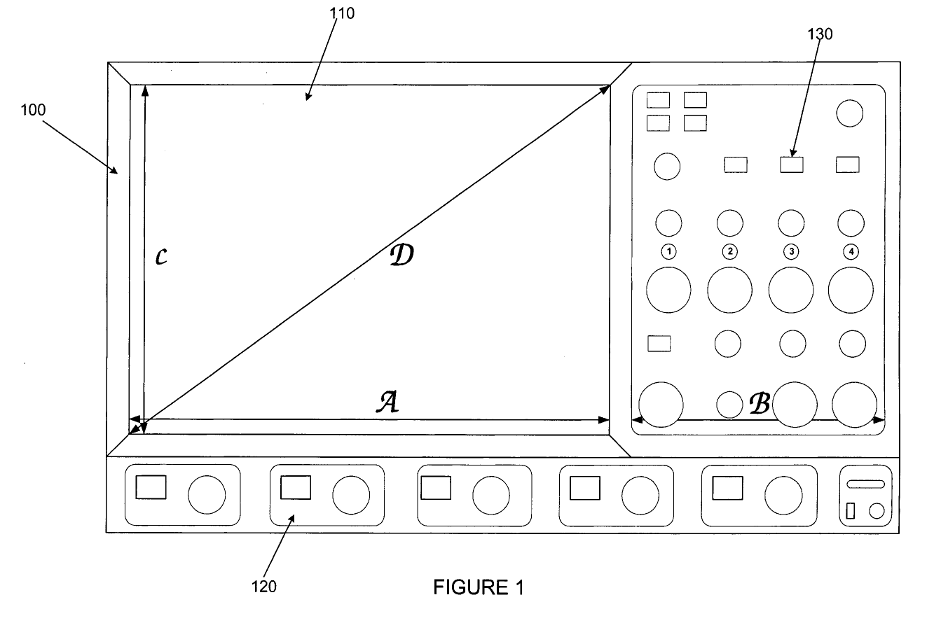

Figure depicts the oscilloscope of FIG. 1 with the removable control panel removed and showing a movable connector employed thereon.

### DETAILED DESCRIPTION OF THE PREFERRED EMBODIMENTS

Referring first to FIG. 1, an oscilloscope 100 is shown. While the invention is described making reference to an oscilloscope, it should be understood that the invention is intended to apply to any type of test and measurement equipment, and to any apparatus including a display and an accompanying control panel. Oscilloscope 100 is preferably provided with a display 110, input/output ports 120 and a control panel 130. Control panel 130 includes knobs, indicators, buttons and the like as is well known in the industry. In FIG. 1, control panel 130 is depicted in a traditional location, thus providing a conventional oscilloscope layout. In such a layout, the screen has display diagonal distance of D=\sqrt{A²+C²} while the width of the control panel is measured at B. However, as will be discussed below, control panel 130 is in fact a removable control panel constructed in accordance with the invention, located in a conventional position.

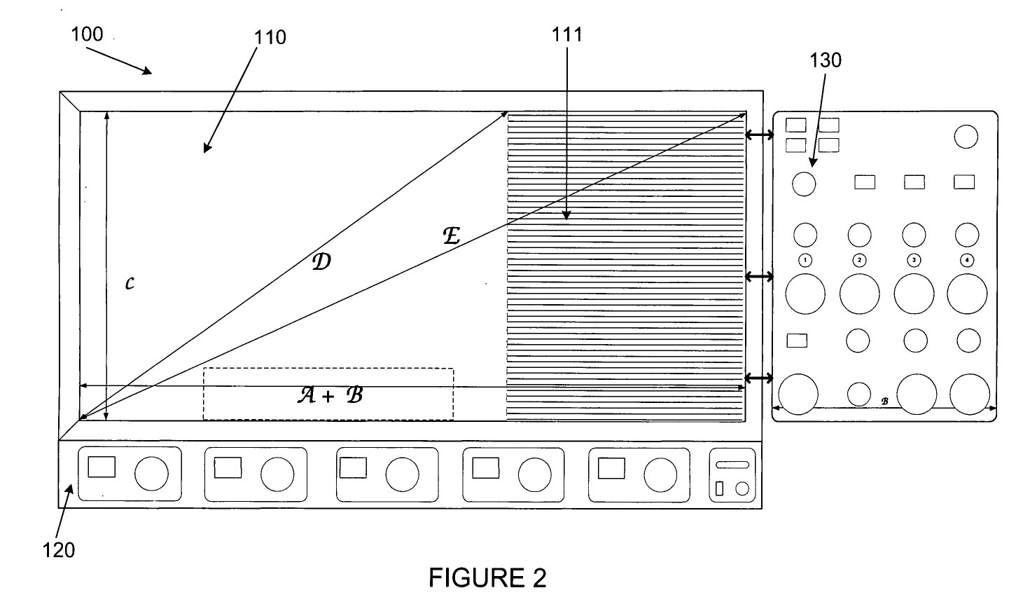

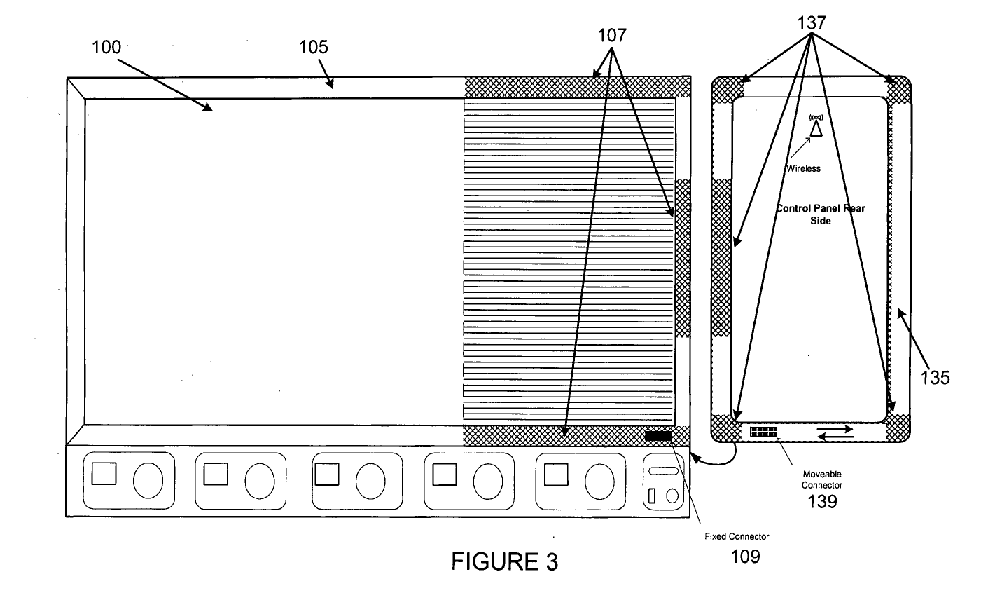

Referring next to FIG. 2, oscilloscope 100 of FIG. 1 is shown with control panel 130 positioned adjacent oscilloscope 130, thus revealing a portion 111 of display 110 that was previously covered by control panel 130. As is shown, the display diagonal distance increases from the above value to E=\sqrt{(A+B)²+C²}, including the area previously covered by control panel 130.

Control panel 130 preferably remains operable when physically disconnected from oscilloscope 100. Thus, control panel may be adapted to communicate with oscilloscope 100 via a wired cable, a wireless link, or any other communication protocol that allows for signals to be transmitted to and from the control panel for use in controlling the operation of oscilloscope 100, and/or the display of information of display 110/111. Such wireless connection may comprise wireless USB, Bluetooth, wireless LAN, ultra wideband, or any other appropriate wireless communication protocol.

Referring next to FIG. 3, an exemplary connection scheme is shown. In such a scheme a bezel 105 of oscilloscope is provided with magnetic or other retentive strips 107.complimentary strips 137 are provided on a rear bezel 130 of removable control panel 130 (as shown). Thus, when replaced, the magnetic or other retentive strips 107 mate with those 137 to releasably fix control panel 130 to oscilloscope 100. When connected, data transfer, power transfer, and battery charging of a rechargeable battery retained in control panel 130 are provided via a connector 109 of oscilloscope 100 mating with a connector 139 positioned also on the rear of control panel 130. Thus, upon the removal of control panel 130, oscilloscope 100 is aware of the movement, and the portion 111 of display 110 is enabled. Further control panel 130 begins data transfer via a provided wireless or wired link as noted above. Communication between connectors 109 and 139 may take place in accordance with any appropriate communication protocol, including but not limited to IEEE 1394, RS 232/422/485, USB, any of the wireless protocols noted above, or the like.

When removed, a user may not prefer to continue use of the controls on control panel 130. Thus, it is possible for a user to disable control panel 130, either before or after removal. The user may further select whether a soft control panel should be available on display 110. If desired, preferably a portion 111 of display 110 displays a simulation of a control panel that may be used by a user in the manner of control panel 130. However, controls are accesses via touch screen control, or via designation by a pointer, such as a computer mouse or the like. This soft control panel may be designed to disappear when not in use to allow the user use of the complete area of display 110, including portion 111 for the display of information when the control panel is not in use. The control panel may be recalled by the user when desired.

Connector 139 may be provided as a slideable connector so that the position of control panel 130 relative to oscilloscope 100 is not fixed. Thus with connector 139 adapted to slide side to side as indicated by the arrows adjacent thereto, it is possible to place control panel in any position between that shown in FIG. 1, and a position in which control panel 130 is partially hanging off the side of oscilloscope 130 with connectors 109 and 139 remaining mated. Of course, any other appropriate connection and mating scheme may be utilized for the retention of control panel adjacent oscilloscope 100 and the mating of connectors 109 and 139, including but not limited to cable connections, snap-fit connections, sliding connections and the like. Furthermore, while a horizontally sliding connector is shown, a vertically sliding connector may be employed. Further, the connector on the oscilloscope housing may also be provided as a moveable or sliding connector.

Referring once again to FIG. 2, in accordance with the invention, a mechanism for attaching control panel to an outside edge of oscilloscope is provided. thus, after removal, control panel may be essentially clipped to the side of oscilloscope 130, thus providing a traditional control panel feel with an improved and increased size display 110, including portion 111 thereof, available to a user for display of information. Mechanisms for connection of control panel 130 in such a manner include those noted above, and any other appropriate mechanical connecting mechanism. Communication similarly may be provided via wireless or wired connection.

Rather than being removed completely, coupling of control panel 130 to oscilloscope 100 may be provided employing a hinge mechanism positioned adjacent the outer edge of oscilloscope 100. Thus, rather than fully detaching, the panel may rotate about the hinge, out of the way of display 110 and portion 111 thereof, giving full access thereto.

While the invention has been described applicable to an oscilloscope, the invention is intended to be equally applicable to other test and measurement apparatuses and to electronic apparatuses in general. Indeed, any application in which a user may benefit from a choice for a larger display may incorporate the invention. Additionally, while the control panel has been shown in its traditional location on the left side of the oscilloscope, it may be provided at any other location covering a portion of the screen. This freedom in positioning may be useful when applying the invention to other test and measurement equipment, or electronic apparatuses in general.

While the control panel is shown covering a portion of the display, it is possible to provide the control panel at any other location, not covering the display. In this manner, the control panel would still provide wireless and /or wired communication for controlling the oscilloscope.

It will thus be seen that the objects set forth above, among those made apparent from the preceding description, are efficiently attained and, since certain changes may be made in the above construction(s) without departing from the spirit and scope of the invention, it is intended that all matter contained in the above description or shown in the accompanying drawing(s) shall be interpreted as illustrative and not in a limiting sense.

It is also to be understood that the following claims are intended to cover all of the generic and specific features of the invention herein described and all statements of the scope of the invention which, as a matter of language, might be said to fall there between.

What is claimed:

1. A test and measurement apparatus, comprising:
a control panel; and
a display having a first portion and a second portion, the second portion of the display being covered by the control panel;
wherein the control panel is adjustable to reveal at least a portion of the second portion of the display.

2. The test and measurement apparatus of claim 1, wherein the second portion of the display is inoperable when covered by the control panel.

3. The test and measurement apparatus of claim 1, wherein the second portion of the display is operable when revealed.

4. The test and measurement apparatus of claim 1, wherein the control panel is slidable away from the second portion of the display.

5. The test and measurement apparatus of claim 4, wherein the control panel comprises a slidable connector on a side thereof facing the test and measurement apparatus, wherein the slidable connector is adapted to be coupled with a connector on the oscilloscope to maintain connection when the control panel is slid relative to the test and measurement apparatus.

6. The test and measurement apparatus of claim 1, wherein the control panel is rotatable away from the second portion of the display.

7. The test and measurement apparatus of claim 1, wherein the control panel is removable.

8. The test and measurement apparatus of claim 7, wherein the control panel is maintained in communicating contact with the test and measurement apparatus when removed via a wired connection.

9. The test and measurement apparatus of claim 7, wherein the control panel is maintained in communication contact with the test and measurement apparatus when removed via a wireless connection.

10. The test and measurement apparatus of claim 9, wherein the removed control panel is operable to control the test and measurement apparatus.

11. The test and measurement apparatus of claim 1, wherein a soft control panel is selectively displayed on the revealed second portion of the display.

12. An electronic apparatus, comprising:
a control panel; and
a display having a first portion and a second portion, the second portion of the display being covered by the control panel:
wherein the control panel is adjustable to reveal at least a portion of the second portion of the display.

13. The apparatus of claim 12, wherein the second portion of the display is inoperable when covered by the control panel.

14. The apparatus of claim 12, wherein the second portion of the display is operable when revealed.

15. The apparatus of claim 12, wherein the control panel is removable.

16. The apparatus of claim 15, wherein the control panel is maintained in communication contact with the apparatus when removed via a wireless connection.

17. The apparatus of claim 16, wherein the control panel is operable to control the apparatus.

18. The apparatus of claim 12, wherein a soft control panel is displayed on the revealed second portion of the display.

19. An oscilloscope, comprising:
a housing;
a control panel releasably fixed to the housing; and
a display having a first portion and a second portion, at least the second portion of the display being covered by the control panel when removably fixed to the housing;
wherein the second portion of the display is inoperable when the control panel is removable fixed to the housing and is operable when the control panel is removed from the housing.

20. The oscilloscope of claim 19, wherein the control panel is operable to control the oscilloscope via a wireless connection when removed from the housing.
